(19) United States
(12) Patent Application Publication
(10) Pub. No.: US 2024/0302301 A1
(43) Pub. Date: Sep. 12, 2024

(54) X-Ray Scatterometry Based Measurements Of Memory Array Structures Stacked With Complex Logic Structures

(71) Applicant: KLA Corporation, Milpitas, CA (US)

(72) Inventors: Sandeep Inampudi, Westford, MA (US); Hyowon Park, Milpitas, CA (US); Daniel Haxton, Lake Forest Park, WA (US); Boxue Chen, San Jose, CA (US); Sungchul Yoo, San Jose, CA (US); Robert D. Press, San Jose, CA (US)

(21) Appl. No.: 18/416,113

(22) Filed: Jan. 18, 2024

Related U.S. Application Data
(60) Provisional application No. 63/450,666, filed on Mar. 8, 2023.

(51) Int. Cl. G01N 23/205; G01N 23/2055; H01L 21/66

(52) U.S. Cl. CPC G01N 23/205; G01N 23/2055; G01N 2223/6116; H01L 22/12

(57) ABSTRACT

Methods and systems for performing measurements of stacked semiconductor structures, e.g., stacked memory and logic structures, based on X-Ray transmission scatterometry measurement data are described herein. In some examples, the scattering response of logic structures is modelled directly in signal space by a mathematical expression including a relatively small number of weighted basis functions. The scattering response of the logic structures and the scattering response of the memory structures determined by an electromagnetic response model are combined, e.g., by summation or convolution. The combined modelled signals are compared to the measured signals at the detector to generate an error signal. The error signal is employed to drive a regression analysis employed to optimize parameter values characterizing the memory structures, values of the weighting coefficients of the signal space model, or both. In other examples, the scattering response of the logic structures is known, and a model is not needed.

### CROSS REFERENCE TO RELATED APPLICATION

The present application for patent claims priority under 35 U.S.C. § 119 from U.S. provisional patent application Ser. No. 63/450,666, filed Mar. 8, 2023, the subject matter of which is incorporated herein by reference in its entirety.

### TECHNICAL FIELD

The described embodiments relate to x-ray metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. A number of metrology based techniques including scatterometry and reflectometry implementations and associated analysis algorithms are commonly used to characterize critical dimensions, film thicknesses, composition and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. For example, modern memory structures are often high-aspect ratio, three-dimensional structures fabricated from opaque materials that make it difficult for optical radiation to penetrate to the bottom layers. Optical metrology tools utilizing infrared to visible light can penetrate many layers of translucent materials, but longer wavelengths that provide good depth of penetration do not provide sufficient sensitivity to small anomalies. In addition, the increasing number of parameters required to characterize complex structures, leads to increasing parameter correlation. As a result, the parameters characterizing the target often cannot be reliably decoupled with available optical measurements.

To overcome penetration depth issues, traditional imaging techniques such as TEM, SEM etc., are employed with destructive sample preparation techniques such as focused ion beam (FIB) machining, ion milling, blanket or selective etching, etc. For example, transmission electron microscopes (TEM) achieve high resolution levels and are able to probe arbitrary depths, but TEM requires destructive sectioning of the specimen. Several iterations of material removal and measurement generally provide the information required to measure the critical metrology parameters throughout a three dimensional structure. But, these techniques require sample destruction and lengthy process times. The complexity and time to complete these types of measurements introduces large inaccuracies due to drift of etching and metrology steps. In addition, these techniques require numerous iterations which introduce registration errors.

Transmission based X-ray scatterometry systems offer the possibility to overcome fundamental challenges associated with high-throughput, non-destructive measurement of many advanced targets (e.g., complex 3D structures, structures smaller than 10 nm, structures employing opaque materials) and measurement applications (e.g., line edge roughness and line width roughness measurements). Traditional X-Ray scatterometry measurement techniques employ indirect methods of measuring physical properties of a specimen under measurement. In some examples, a physics-based measurement model is created that attempts to predict raw measurement signals based on assumed values of one or more model parameters. The measurement model includes parameters associated with the metrology tool itself, e.g., system parameters and parameters associated with the specimen under measurement. When solving for parameters of interest, some specimen parameters are treated as fixed valued and other specimen parameters of interest are floated, i.e., resolved based on the raw measurement signals.

System parameters are parameters used to characterize the metrology tool. Exemplary system parameters include angle of incidence (AOI), azimuth angle, beam divergence, etc. Specimen parameters are parameters used to characterize the specimen (e.g., material and geometric parameters characterizing the structure (s) under measurement). For a thin film specimen, exemplary specimen parameters include refractive index, dielectric function tensor, nominal layer thickness of all layers, layer sequence, etc. For a CD specimen, exemplary specimen parameters include geometric parameter values associated with different layers, refractive indices associated with different layers, etc. For measurement purposes, the system parameters and many of the specimen parameters are treated as known, fixed valued parameters. However, the values of one or more of the specimen parameters are treated as unknown, floating parameters of interest.

In some examples, the values of the floating parameters of interest are resolved by an iterative process (e.g., regression) that produces the best fit between theoretical predictions and experimental data. The values of the unknown, floating parameters of interest are varied and the model output values are calculated and compared to the raw measurement data in an iterative manner until a set of specimen parameter values are determined that results in a sufficiently close match between the model output values and the experimentally measured values. In some other examples, the floating parameters are resolved by a search through a library of pre-computed solutions to find the closest match.

The indirect approach to estimating values of parameters of interest is challenging to implement due to the complexity of the measurement model required to adequately represent light scattered from a complex semiconductor structure. The measurement model must properly model both the device under measurement and the measurement system to adequately model the physical interaction between the two, i.e., the light scattered from the device under measurement. This difficulty is magnified for transmission based scatterometry measurements of memory array structures stacked with corresponding complex logic structures.

Many modern memory devices include an array of memory structures stacked on corresponding logic structures, rather than side by side. For example, modern VNAND memory devices include an array of memory structures fabricated over complex logic structures, e.g., complementary metal oxide semiconductor (CMOS) structures, employed to control the memory device. In some examples, this architecture is referred to as CMOS Under Array (CUA).

Unfortunately, the scattering images of VNAND memory structures measured using a transmission based scatterometry tool are contaminated with scatterometry signals from the underlying CMOS structures. Regression on the contaminated scattering images is prone to higher root mean squared errors at the estimated values of the parameters characterizing the measured array of memory structures.

In the abstract, measurements of memory structures derived from scatterometry signals contaminated by signals from underlying CMOS structures could be achieved using a three-dimensional (3D) electromagnetic model that captures the combined electromagnetic response of both the memory structures and the underlying CMOS structures. However, this approach has not proven to be feasible due to the complexity of the internal structural elements and critical dimensions of the underlying CMOS structures.

Rather than attempt a detailed 3D electromagnetic model of the combined memory and underlying CMOS structures, a more practical approach is to approximate the underlying CMOS structures as a 3D grating that mimics the scatterometry signals measured at the detector due to the CMOS structures. The 3D grating structure is characterized by far fewer critical parameters than a 3D electromagnetic model of the CMOS structures. Thus, the required model development effort and computational burden are tractable.

The estimated pitch lengths of the 3D grating in the lateral directions derived from scatterometry signals projected onto the detector are an order of magnitude higher than the pitch lengths of the memory structures. Thus, the electromagnetic modelling of memory structures and underlying CMOS structures need to be decoupled in a multi-model simulation. In this approach, the scattering signals from the underlying CMOS structures are computed for a larger set of diffraction orders that represent a supercell lattice with CMOS and memory units, and then diffraction orders are grouped into batches based on pitch mismatch ratio between the CMOS and memory structures. Separate electromagnetic simulations of the memory structure are performed for each batch using the output of the CMOS structure corresponding to each batch as input to the electromagnetic simulation of the memory structure. The order intensities of the total set of diffraction orders are then regrouped during the system modeling phase of the regression process to determine the final simulated scattering image.

Although multi-model simulation is the best-known approach to account for signal contamination due to underlying CMOS structures in transmission based measurements of memory structures, the approach suffers from two major disadvantages. First, the approximation of the underlying CMOS structures as a 3D dimensional grating is highly inaccurate. Isolated regressions on CMOS only signals using the 3D grating structure always converge to low accurate solutions with large residual differences between the measured and simulated image. During the regression on the response of the total structure using the multi-model approach, this large discrepancy translates into large errors in the determination of the structural characteristics of the memory structure. Second, the simulations of the memory structure performed for multiple batches are computationally burdensome. Thus, the time to solution becomes impractical for many measurement applications.

In summary, the computational burden and development time required to generate an accurate measurement model for transmission based measurements of memory structures stacked with corresponding CMOS structures is a significant barrier to broad adoption of transmission based scatterometry measurement techniques.

To further improve device performance, the semiconductor industry continues to focus on vertical integration, rather than lateral scaling. Thus, accurate measurement of complex, fully three dimensional structures is crucial to ensure viability and continued scaling improvements. Future metrology applications present challenges for metrology due to increasingly small resolution requirements, multi-parameter correlation, increasingly complex geometric structures including high aspect ratio structures, and increasing use of opaque materials. Thus, methods and systems for improved scatterometry based measurements are desired.

### SUMMARY

Methods and systems for performing measurements of stacked semiconductor structures based on X-Ray transmission scatterometry measurement data are described herein. In some embodiments, the stacked semiconductor memory structures include logic structures and memory structures. In general, the disclosed measurement methods and systems enable isolated characterization of a particular metrology target stacked with a multi-patterned structure.

In one aspect, the scattering response of logic structures is modelled directly in signal space by a mathematical expression including a relatively small number of weighted basis functions. The scattering response of the logic structures measured at the detector includes a relatively small number of dominant features that are accurately represented by a small number of weighted basis functions.

In a further aspect, the scattering response of the logic structures determined by a signal space model and the scattering response of the memory structures determined by an electromagnetic response model are combined. The combined modelled signals are compared to the measured signals at the detector to generate an error signal. The error signal is employed to drive a regression analysis employed to optimize parameter values characterizing the memory structures, values of the weighting coefficients of the signal space model, or both.

In some embodiments, the combination of the set of signals indicative of the scattering response of the logic structure and the set of signals indicative of the scattering response of the memory structure involves a summation of each corresponding element of the sets of signals. For example, at each pixel location, the signal indicative of the scattering response of the logic structure and the signal indicative of the scattering response of the memory structure are summed. In other examples, at each diffraction order, the diffraction order intensity indicative of the scattering response of the logic structure and the diffraction order intensity indicative of the scattering response of the memory structure are summed.

In some other embodiments, the combination of the set of signals indicative of the scattering response of the logic structure and the set of signals indicative of the scattering response of the memory structure involves a convolution of the signals indicative of the scattering response of the logic structure and the signals indicative of the scattering response of the memory structure. In these embodiments, the scattering response signals are pixel intensity images.

In another aspect, the scattering response of the logic structures in the absence of the memory structures is known at each measurement site under measurement. Under these conditions, parameters of interest characterizing the memory structures are estimated without a model of the scattering response of the logic structures.

In one example, x-ray scatterometry measurements of the logic structures are performed at the measurement sites under measurement before memory structures are fabricated, i.e., earlier in the semiconductor manufacturing process flow. In some examples, the known scattering response of the logic structures is separated from the measured signals at each of the measurement sites to generate an estimated scattering response of the memory structures at the detector. The estimated scattering response of the memory structures is compared to the scattering response of the memory structures determined by an electromagnetic response model to generate an error signal. The error signal is employed to drive a regression analysis employed to optimize parameter values characterizing the memory structures.

In another example, the known scattering response of the logic structures is provided as the illumination input to the electromagnetic response model of the memory structures. In this example, the electromagnetic response model generates an estimated scattering response of the stacked structure including the logic and memory structures. The estimated scattering response of the stacked structure is compared to the measured signals at the detector to generate an error signal. The error signal is employed to drive a regression analysis employed to optimize parameter values characterizing the memory structures.

In some embodiments, the scattering response of the logic structures in the absence of the memory structures is unknown at any measurement site on a wafer, or set of wafers, under measurement. In some of these embodiments, a Fourier decomposition is employed to operate on signals indicative of the measured scattering response of the stacked structure. The Fourier decomposition separates the portion of the scattering response due to the logic structures and the scattering response due to the memory structures by spatial frequency. In these embodiments, logic structures are characterized by dominant pitch lengths that are significantly different from the dominant pitch lengths of the memory structures. Thus, a spatial Fourier decomposition of the measured response of the stacked structure separates the contributions to the measured signals by the logic structure and the memory structure by spatial frequency. In these embodiments, the spatial frequencies associated with the logic structures are selected and estimated signals indicative of the scattering response of the logic structure are generated by inverse Fourier transform. The resulting estimated signals can be employed for analysis as described herein.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a transmission based, X-Ray metrology system 100 configured to perform measurements of stacked semiconductor structures based on scatterometry measurement data in accordance with the methods described herein.

FIG. 2 is a diagram illustrative of an embodiment of an exemplary stacked structure measurement engine 150 configured to resolve specimen parameter values characterizing a stacked semiconductor structure based on scatterometry measurement data in accordance with the methods described herein.

FIG. 3 is a diagram illustrative of another embodiment of an exemplary stacked structure measurement engine 170 configured to resolve specimen parameter values characterizing a stacked semiconductor structure based on scatterometry measurement data in accordance with the methods described herein.

FIG. 4 is a diagram illustrative of another embodiment of an exemplary stacked structure measurement engine 180 configured to resolve specimen parameter values characterizing a stacked semiconductor structure based on scatterometry measurement data in accordance with the methods described herein.

FIG. 5 is a simplified diagram illustrative of a beam of x-ray illumination light 204 incident on a stacked structure 200.

FIG. 6 is a simplified diagram illustrative of a summation approach to the mixing of signals indicative of the scattering response of different structural layers of a stacked semiconductor structure 200.

FIG. 7 is a simplified diagram illustrative of a convolution approach to the mixing of signals indicative of the scattering response of different structural layers of a stacked semiconductor structure 200.

FIG. 8 depicts a plot 190 indicative of the fitting error associated with a number of different measurement sites for three different models of logic scattering signals captured at the detector plane.

FIG. 9 depicts a plot 210 of fitting residuals associated with sixteen different measurements of stacked structures.

FIG. 10 depicts a plot 215 of computational time to result associated with the sixteen different measurements of stacked structures depicted in FIG. 9.

FIG. 11 is a plot 220 illustrative of the scattering response of logic structures at the detector plane.

FIG. 12 is a plot 230 illustrative of a Fourier decomposition of the scattering response of the logic structures at the detector plane.

FIG. 13 is a plot 240 illustrative of the scattering response of memory structures at the detector plane.

FIG. 14 is a plot 250 illustrative of a Fourier decomposition of the scattering response of the memory structures at the detector plane.

FIG. 15 depicts a flowchart illustrative of an exemplary method 300 of performing measurements of stacked semiconductor structures based on scatterometry measurement data as described herein.

### DETAILED DESCRIPTION

Reference will now be made in detail to background examples and some embodiments of the invention, examples of which are illustrated in the accompanying drawings.

Methods and systems for performing measurements of stacked semiconductor structures based on X-Ray transmission scatterometry measurement data are described herein. In some embodiments, the stacked semiconductor memory structures include logic structures and memory structures.

In one aspect, the scattering response of the logic structures is modelled directly in signal space, e.g., modelled image at the detector, by a mathematical expression including a relatively small number of weighted basis functions. The logic structures may or may not be periodic structures. If the logic structures are periodic, they are characterized by pitch lengths that are significantly larger than the wavelength of the X-Ray illumination radiation employed to perform measurements. Whether the logic structures are periodic or not, the scattering response measured at the detector includes a relatively small number of dominant features that are accurately represented by a small number of weighted basis functions. In some examples, the scattering response of the logic structures measured at the detector is more accurately modelled with five weighted basis functions than an ad hoc grating model characterized by more than 20 structural parameters. In some of these examples, the match between measured and modelled photon counts at the detector is increased by 50% using a signal space model instead of an ad hoc grating model.

In a further aspect, the scattering response of the logic structures determined by a signal space model and the scattering response of the memory structures determined by an electromagnetic response model are combined. The combined modelled signals are compared to the measured signals at the detector to generate an error signal. The error signal is employed to drive a regression analysis employed to optimize parameter values characterizing the memory structures, values of the weighting coefficients of the signal space model, or both.

In another aspect, the scattering response of the logic structures in the absence of the memory structures is known at each measurement site under measurement. Under these conditions, parameters of interest characterizing the memory structures are estimated without a model of the scattering response of the logic structures.

In one example, x-ray scatterometry measurements of the logic structures are performed at the measurement sites under measurement before memory structures are fabricated, i.e., earlier in the semiconductor manufacturing process flow. In some examples, the known scattering response of the logic structures is separated from the measured signals at each of the measurement sites to generate an estimated scattering response of the memory structures at the detector. The estimated scattering response of the memory structures is compared to the scattering response of the memory structures determined by an electromagnetic response model to generate an error signal. The error signal is employed to drive a regression analysis employed to optimize parameter values characterizing the memory structures.

In another example, the known scattering response of the logic structures is provided as the illumination input to the electromagnetic response model of the memory structures. In this example, the electromagnetic response model generates an estimated scattering response of the stacked structure including the logic and memory structures. The estimated scattering response of the stacked structure is compared to the measured signals at the detector to generate an error signal. The error signal is employed to drive a regression analysis employed to optimize parameter values characterizing the memory structures.

In general, the disclosed measurement methods and system enable isolated characterization of a particular metrology target stacked with a multi-patterned structure.

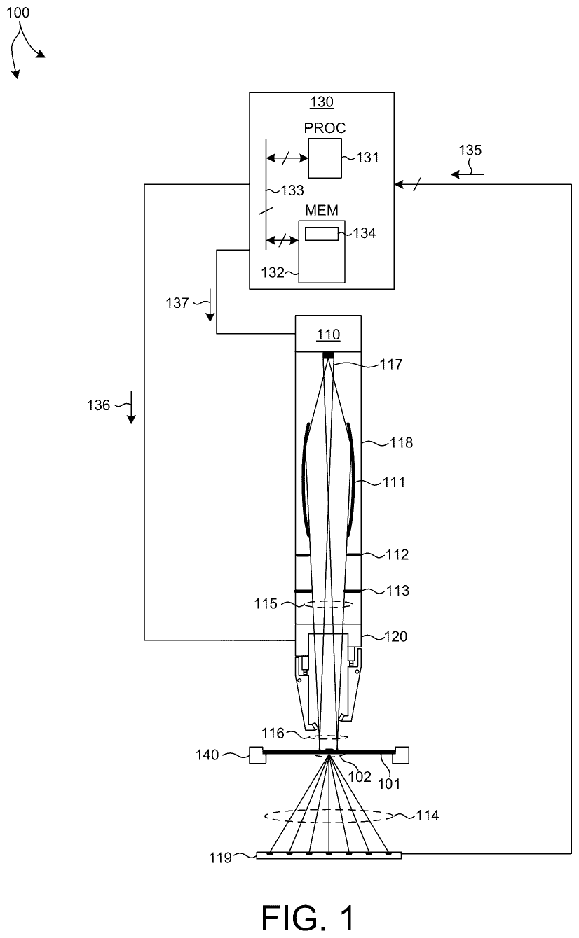

FIG. 1 illustrates an embodiment of a Transmission, Small-Angle X-Ray Scatterometry (T-SAXS) metrology tool 100 for measuring characteristics of a specimen in accordance with the exemplary methods presented herein. As shown in FIG. 1, the system 100 may be used to perform T-SAXS measurements over an inspection area 102 of a specimen 101 illuminated by an illumination beam spot.

In the depicted embodiment, metrology tool 100 includes an x-ray illumination source 110 configured to generate x-ray radiation suitable for T-SAXS measurements. In some embodiments, the x-ray illumination source 110 is configured to generate wavelengths between 0.01 nanometers and 1 nanometer. In general, any suitable high-brightness x-ray illumination source capable of generating high brightness x-rays at flux levels sufficient to enable high-throughput, inline metrology may be contemplated to supply x-ray illumination for T-SAXS measurements. In some embodiments, an x-ray source includes a tunable monochromator that enables the x-ray source to deliver x-ray radiation at different, selectable wavelengths. As depicted in FIG. 1, computing system 130 is configured to control the x-ray illumination generated by x-ray illumination source 110 via control signals 137.

In some embodiments, one or more x-ray sources emitting radiation with photon energy greater than 15 keV are employed to ensure that the x-ray source supplies light at wavelengths that allow sufficient transmission through the entire device as well as the wafer substrate. By way of non-limiting example, any of a particle accelerator source, a liquid anode source, a rotating anode source, a stationary, solid anode source, a microfocus source, a microfocus rotating anode source, a plasma based source, and an inverse Compton source may be employed as x-ray illumination source 110. In one example, an inverse Compton source available from Lyncean Technologies, Inc., Palo Alto, California (USA) may be contemplated. Inverse Compton sources have an additional advantage of being able to produce x-rays over a range of photon energies, thereby enabling the x-ray source to deliver x-ray radiation at different, selectable wavelengths.

Exemplary x-ray sources include electron beam sources configured to bombard solid or liquid targets to stimulate x-ray radiation. Methods and systems for generating high brightness, liquid metal x-ray illumination are described in U.S. Pat. No. 7,929,667, issued on Apr. 19, 2011, to KLA-Tencor Corp., the entirety of which is incorporated herein by reference.

X-ray illumination source 110 produces x-ray emission over a source area having finite lateral dimensions (i.e., non-zero dimensions orthogonal to the beam axis. Focusing optics 111 focuses source radiation onto a metrology target located on specimen 101. The finite lateral source dimension results in finite spot size 102 on the target defined by the rays 117 coming from the edges of the source. In some embodiments, focusing optics 111 includes elliptically shaped focusing optical elements.

A beam divergence control slit 112 is located in the beam path between focusing optics 111 and beam shaping slit mechanism 120. Beam divergence control slit 112 limits the divergence of the illumination provided to the specimen under measurement. An additional intermediate slit 113 is located in the beam path between beam divergence control slit 112 and beam shaping slit mechanism 120. Intermediate slit 113 provides additional beam shaping. In general, however, intermediate slit 113 is optional.

Beam shaping slit mechanism 120 is located in the beam path immediately before specimen 101. In one aspect, the slits of beam shaping slit mechanism 120 are located in close proximity to specimen 101 to minimize the enlargement of the incident beam spot size due to beam divergence defined by finite source size. In one example, expansion of the beam spot size due to shadow created by finite source size is approximately one micrometer for a 10 micrometer x-ray source size and a distance of 25 millimeters between the beam shaping slits and specimen 101. As depicted in FIG. 1, computing system 130 is configured to control the size and shape of illumination beam 116 generated by beam shaping slit mechanism 120 via control signals 136.

In some embodiments, beam shaping slit mechanism 120 includes multiple, independently actuated beam shaping slits (i.e., blades). In one embodiment, beam shaping slit mechanism 120 includes four independently actuated beam shaping slits. These four beams shaping slits effectively block a portion of incoming beam 115 and generate an illumination beam 116 having a box shaped illumination cross-section.

In the embodiment depicted in FIG. 1, focusing optics 111, slits 112 and 113, and beam shaping slit mechanism 120 are maintained in a controlled environment (e.g., vacuum) within a flight tube 118.

In general, x-ray optics shape and direct x-ray radiation to specimen 101. In some examples, the x-ray optics include an x-ray monochromator to monochromatize the x-ray beam that is incident on the specimen 101. In some examples, the x-ray optics collimate or focus the x-ray beam onto measurement area 102 of specimen 101 to less than 1 milliradian divergence using multilayer x-ray optics. In these examples, the multilayer x-ray optics function as a beam monochromator, also. In some embodiments, the x-ray optics include one or more x-ray collimating mirrors, x-ray apertures, x-ray beam stops, refractive x-ray optics, diffractive optics such as zone plates, Montel optics, specular x-ray optics such as grazing incidence ellipsoidal mirrors, polycapillary optics such as hollow capillary x-ray waveguides, multilayer optics or systems, or any combination thereof. Further details are described in U.S. Patent Publication No. 2015/0110249, the content of which is incorporated herein by reference it its entirety.

X-ray detector 119 collects x-ray radiation 114 scattered from specimen 101 and generates an output signals 135 indicative of properties of specimen 101 that are sensitive to the incident x-ray radiation in accordance with a T-SAXS measurement modality. In some embodiments, scattered x-rays 114 are collected by x-ray detector 119 while specimen positioning system 140 locates and orients specimen 101 to produce angularly resolved scattered x-rays.

In some embodiments, a T-SAXS system includes one or more photon counting detectors with high dynamic range (e.g., greater than 105). In some embodiments, a single photon counting detector detects the position and number of detected photons.

In some embodiments, the x-ray detector resolves one or more x-ray photon energies and produces signals for each x-ray energy component indicative of properties of the specimen. In some embodiments, the x-ray detector 119 includes any of a CCD array, a microchannel plate, a photodiode array, a microstrip proportional counter, a gas filled proportional counter, a scintillator, or a fluorescent material.

In this manner the X-ray photon interactions within the detector are discriminated by energy in addition to pixel location and number of counts. In some embodiments, the X-ray photon interactions are discriminated by comparing the energy of the X-ray photon interaction with a predetermined upper threshold value and a predetermined lower threshold value. In one embodiment, this information is communicated to computing system 130 via output signals 135 for further processing and storage.

In a further aspect, a transmission based, X-Ray scatterometry system, e.g., TSAXS measurement system 100, is employed to determine properties of a stacked structure (e.g., structural parameter values) based on one or more diffraction orders of scattered light. In the embodiment depicted in FIG. 1, computing system 130 is configured as a stacked structure measurement engine configured to implement stacked structure measurement functionality as described herein.

As depicted in FIG. 1, metrology tool 100 includes a computing system 130 employed to acquire signals 135 generated by detector 119 and determine properties of the stacked structure based at least in part on the acquired signals in accordance with transmission based, scatterometry measurement techniques described herein. The transmission based measurements described herein are based on penetration of the incident X-Ray illumination radiation through the semiconductor wafer under measurements. As depicted in FIG. 1, the beam of x-ray illumination light 116 is incident on one side of a semiconductor wafer 101 and the light 114 scattered from the measured structures is collected from the opposite side of the semiconductor wafer 101.

In some embodiments, a transmission based, X-Ray measurement system is configured to estimate a value of a parameter of interest characterizing a memory structure of a stacked structure including both the memory structure and a corresponding logic structure. The determination of the value of the parameter of interest is based on a set of signals indicative of a scattering response of the logic structure without the memory structure and the detected image of light scattered from the stacked structure. The estimating of the value of the parameter of interest involves an electromagnetic response model of the memory structure configured to generate the set of signals indicative of the scattering response of the memory structure.

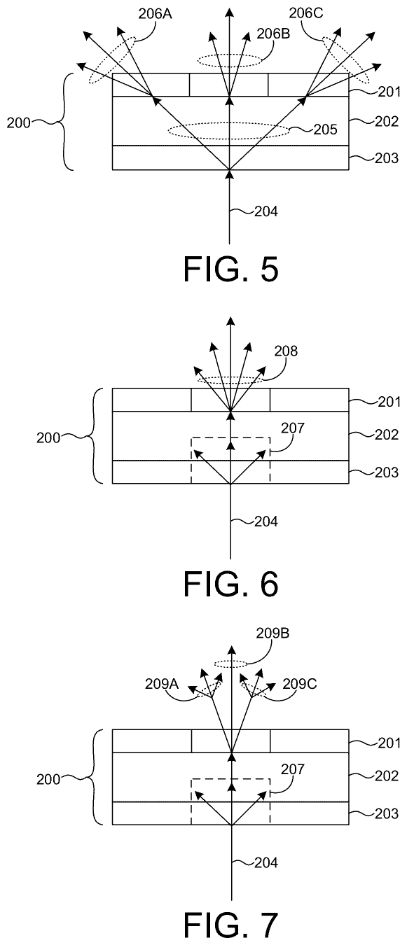

In one aspect, x-ray illumination source 110 is configured to generate a beam of x-ray illumination light 116 incident on a stacked structure under measurement. FIG. 5 is a simplified diagram illustrative of a stacked structure 200 in one embodiment. As depicted in FIG. 5, stacked structure 200 includes an array of memory structures 201 stacked with corresponding logic structures 203. In the embodiment depicted in FIG. 5, the memory structures 201 are separated from logic structures 203 by an unpatterned, intermediate layer 202. However, in general, intermediate layer 202 is optional. In some embodiments, memory structures 201 include an array of NAND memory array structures and logic structures 203 are CMOS logic structures. As depicted in FIG. 5, X-Ray illumination beam 204 is incident on logic structures 203, which causes scattering of X-Ray illumination light 205 through intermediate layer 202. The scattered illumination light 205 is, in turn, incident on memory structure 201 at different locations. The incident scattered illumination light 205 causes scattering 206A-C, from each of the different locations, respectively. The scattered light 206A-C is collected and detected at an imaging detector of a transmission based, X-Ray scatterometry measurement system, e.g., detector 119 of TSAXS measurement system 100 depicted in FIG. 1. Each detected image includes a large number of diffraction orders of scattered light. For example, the number of diffraction orders detected from stacked structure 200 may be approximated as the number of diffraction orders scattered from the memory structures 201 multiplied by the number of diffraction orders scattered from the logic structures 203 at each scattering location.

As depicted in FIG. 5, the beam of x-ray illumination light 204 is incident on the logic structures 203 and scatters from the logic structures 203 onto the memory structures 201. However, in general, the measurement may be configured such that the beam of x-ray illumination light 204 is incident on the memory structures 201 and scatters from the memory structures 201 onto the logic structures 203. Similarly, in some embodiments, stacked structure 200 is fabricated on a semiconductor substrate such that logic structures 203 are fabricated before memory array structures 201, i.e., logic structures 203 are fabricated at lower layers than memory structures 201. However, in some other embodiments, stacked structure 200 is fabricated on a semiconductor substrate such that logic structures 203 are fabricated after memory array structures 201, i.e., memory structures 201 are fabricated at lower layers than logic structures 203.

In general, the scattering response signals or scattering response images described herein refer to pixel intensity values at the detector plane or diffraction order intensity values. Diffraction order intensity values are not directly measured by a transmission based, X-ray scatterometry system, but are derived from measured pixel intensities at the detector plane. However, synthetically generated diffraction order intensities may be computed directly. In some embodiments, it is desirable to compute and mathematically operate on diffraction order intensities to reduce computational effort.

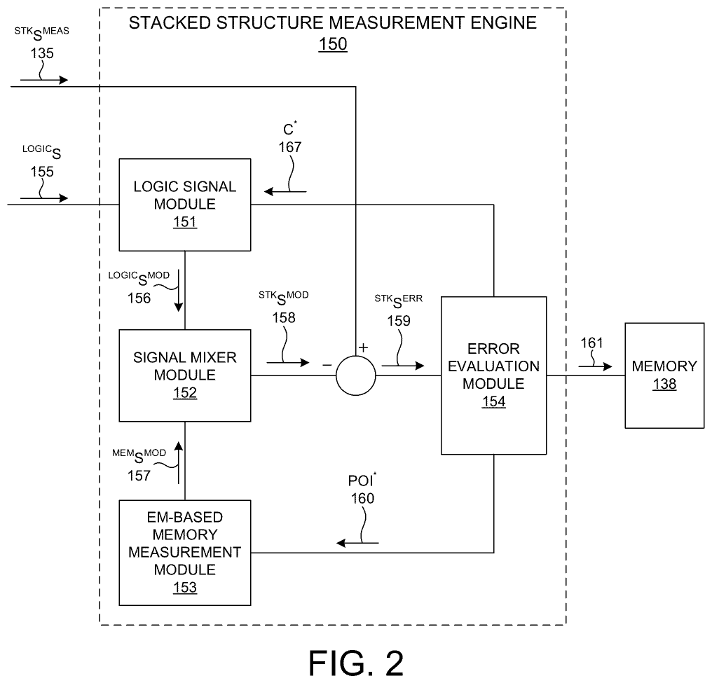

FIG. 2 is a diagram illustrative of a stacked structure measurement engine 150 implemented by computing system 130 in one embodiment. As depicted in FIG. 2, stacked structure measurement engine 150 includes logic signal module 151, signal mixer module 152, electromagnetic based memory measurement module 153, and error evaluation module 154.

As depicted in FIG. 2, logic signal module 151 receives a set of signals, ^{LOGIC}S 155 indicative of the scattering response of a logic structure without a memory structure at a number of measurement sites on one or more wafers. In some embodiments, ^{LOGIC}S 155 are scattering response images generated by actual measurements performed by a transmission based X-Ray scatterometry system before the memory structures are fabricated. In some of these embodiments, ^{LOGIC}S 155 includes a library of scattering response images collected from many samples before the memory structures are fabricated. In some other embodiments, ^{LOGIC}S 155 are synthetic scattering response images generated by simulation of the scattering response of the logic structure over a range of values of process variables. In some of these embodiments, ^{LOGIC}S 155 includes a library of scattering response images computed by simulation. The synthetically generated scattering response images are generated based on the simulation of measurements performed before the memory structures are fabricated. In general, a library of measurements may be assembled from actual measurements by a transmission based X-ray scatterometry system, synthetically generated measurements, or both.

In one aspect, logic signal module 151 generates a mathematical model of the received set of signals, ^{LOGIC}S 155. In some examples, the mathematical model is generated by determining a set of one or more basis functions and values of corresponding weighting coefficients that best fit the received set of signals 155. Exemplary mathematical analysis techniques include principal component analysis, Fourier based analyses, such as discrete cosine transform analysis, etc. The mathematical model of the signals indicative of the scattering response of the logic structure directly models the scattering response signals without explicit modeling of the geometry of the logic structure and its electromagnetic response to the illumination light.

In one example, the received signals, ^{LOGIC}S 155 are expanded into a set of common basis functions defined by a singular value decomposition of the received signals. The modelled signal at each image location is computed as a linear combination of the basis functions as illustrated by Equation (1),

$${}^{LOGIC} {S}^{MOD} = {\sum }_{i = 1}^{N} {C}_{i} {S}_{i} \qquad ( 1 )$$

where ^{LOGIC}S^{MOD}, is the modelled logic signal, Sᵢ, are the basis functions, e.g., principal components, computed using the received set of signals, ^{LOGIC}S 155, N is the number of basis functions, and Cᵢ, are the weighting coefficient values corresponding to the basis functions.

The signal space model described by Equation (1) is generated by relatively simple matrix calculations that are performed with significantly less computational effort than a full electromagnetic simulation of an ad hoc grating structure, e.g., two orders of magnitude less computational effort. In addition, the resulting signal space model more accurately represents the logic scattering signals captured at the detector plane compared to an ad hoc grating representation.

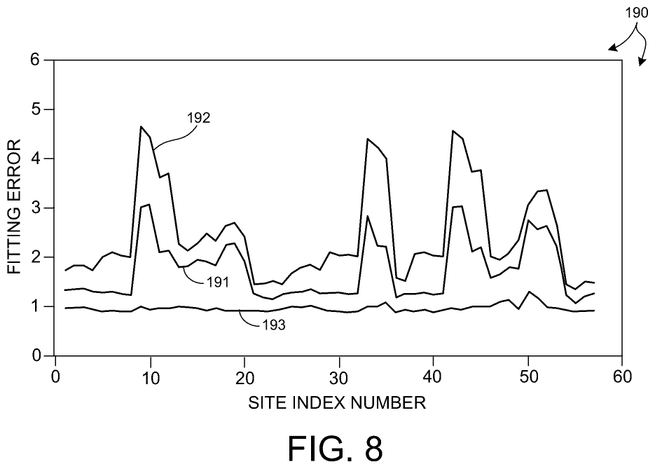

FIG. 8 depicts a plot 190 indicative of the fitting error associated with a number of different measurement sites for three different models of logic scattering signals captured at the detector plane. Plotlines 191 and 192 are the fitting errors associated with two different ad hoc grating models employed to model the scattering response of logic structures. Plotline 193 is the fitting error associated with a principal components based model of the scattering response of the logic structures in signal space, i.e., at the detector plane. As illustrated by FIG. 8, the principal components based model more accurately represents the modelled detector images with significantly reduced computational effort, e.g., one to two orders of magnitude reduction in computational effort.

In another aspect, logic signal module 151 generates a set of signals, ^{LOGIC}S^{MOD} 156, indicative of the modelled scattering response of the logic structure without the memory structure at the detector for a particular measurement site based on the mathematical model of the received set of signals ^{LOGIC}S 155. As described hereinbefore, the values of ^{LOGIC}S^{MOD} 156 depend on the values of the weighting coefficients, C, employed. The set of signals, ^{LOGIC}S^{MOD} 156, is communicated to signal mixer module 152.

In addition, electromagnetic-based memory measurement module 153 generates a set of signals, ^{MEM}S^{MOD} 157, indicative of the modelled scattering response of the memory structure without the logic structure at the detector for the same measurement site. The electro-magnetic-based memory measurement module 153 employs an electromagnetic response simulator to predict the scattering response of the memory structure based on values of one or more parameters of interest characterizing the memory structure under measurement. The electromagnetic response simulator may be an analytical model or library-based simulator. In some embodiments, the electromagnetic response simulator is a trained, machine-learning based model of the electromagnetic response of the memory structure. As depicted in FIG. 2, the set of signals, ^{MEM}S^{MOD} 157, is communicated to signal mixer module 152.

In a further aspect, the set of signals indicative of the scattering response of the logic structure and the set of signals indicative of the scattering response of the memory structure are combined by signal mixer module 152 to generate a set of signals indicative of the scattering response of the stacked structure including the logic and memory structures. In a full electromagnetic simulation of the scattering response of a stacked structure, an electromagnetic solver couples the scattering effects from the logic and memory structures. However, as described hereinbefore, this approach is computationally infeasible. Signal mixer module 152 combines the set of signals indicative of the scattering response of the logic structure and the set of signals indicative of the scattering response of the memory structure without additional electromagnetic simulations.

In some embodiments, the combination of the set of signals indicative of the scattering response of the logic structure and the set of signals indicative of the scattering response of the memory structure involves a summation of each corresponding element of the sets of signals. For example, at each pixel location, the signal indicative of the scattering response of the logic structure and the signal indicative of the scattering response of the memory structure are summed. In other examples, at each diffraction order, the diffraction order intensity indicative of the scattering response of the logic structure and the diffraction order intensity indicative of the scattering response of the memory structure are summed. In many examples, the coupling between the logic and memory scattering signals is relatively weak due significant differences between the pitch lengths of the logic and memory structures. In these examples, combining the scattering signals by summation of pixel intensity values at each pixel, or diffraction order intensity at each diffraction order, results in relatively small errors. In some examples, the fitting residuals of an image of summed pixel intensity values compared to a simulated image of a measurement of a stacked structure are within a 6% noise floor.

FIG. 6 is a diagram of stacked structure 200 illustrative of the summation approach to signal mixing. As depicted in FIG. 7, X-Ray illumination beam 204 is incident on logic structures 203, which causes scattering of X-Ray illumination light 207. In addition, X-Ray illumination beam 204 is incident on memory structures 201, which also induces a scattering response. Scattered X-Ray illumination light 207 is effectively added to the scattering response of the memory structures 201 at the location of incidence of X-Ray illumination beam 204 on memory structures 201 to estimate the scattering response 208 of the stacked structure 200.

In some other embodiments, the combination of the set of signals indicative of the scattering response of the logic structure and the set of signals indicative of the scattering response of the memory structure involves a convolution of the signals indicative of the scattering response of the logic structure and the signals indicative of the scattering response of the memory structure. In these embodiments, the scattering response signals are pixel intensity images.

FIG. 7 is a diagram of stacked structure 200 illustrative of the convolution approach to signal mixing. As depicted in FIG. 7, X-Ray illumination beam 204 is incident on logic structures 203, which causes scattering of X-Ray illumination light 207. In addition, X-Ray illumination beam 204 is incident on memory structures 201, which also induces a scattering response. Scattered X-Ray illumination light 207 is convolved with the scattering response of the memory structures 201 at the detector plane to estimate the scattering response 209A-C of the stacked structure 200. In other examples, the X-Ray illumination beam is first incident on memory structures, which causes scattering of X-Ray illumination light. In addition, the X-Ray illumination beam is subsequently incident on logic structures, which also induces a scattering response. In these examples, the X-Ray illumination light scattered from the memory structures is convolved with the scattering response of the logic structures at the detector plane to estimate the scattering response of a stacked structure.

As depicted in FIG. 2, signal mixer module 152 generates signals indicative of a modelled scattering response of a stacked structure, ^{STK}S^{MOD} 158, based on the signals, ^{LOGIC}S^{MOD} 156, indicative of the modelled scattering response of the logic structure, and the signals, ^{MEM}S^{MOD} 157, indicative of the modelled scattering response of the memory structure. Stacked structure measurement engine 150 determines a difference between the modelled scattering response of a stacked structure, ^{STK}S^{MOD} 158, and signals indicative of the measured scattering response of the stacked structure, ^{STK}S^{MEAS} 135. The difference is a set of signals, ^{STK}S^{ERR} 159, indicative of the error between ^{STK}S^{MEAS} 135 and ^{STK}S^{MOD} 158.

Error evaluation module 154 generates updates values of the parameters of interest, POI* 160, values of weighting coefficients, C* 167, or both, based on the error signals ^{STK}S^{ERR} 159 as part of a regression analysis that minimizes the difference between the measured and modelled scattering response of the stacked structure at the detector. The updated values of POI* 160 are communicated to EM-based memory measurement module 153 to update the modelled scattering response of the memory structure in a subsequent iteration of the regression. Similarly, updated values of C* 167, are communicated to logic signal module 151 to update the modelled scattering response of the logic structure in the subsequent iteration of the regression. The regression analysis iterates until the error signals, ^{STK}S^{ERR} 159, fall within acceptable limits, or the number of iterations reaches a limit. The resulting values of the parameters of interest 161 characterizing the memory structure are communicated to memory 138.

In general, modelling of the scattering response of the logic structures in signal space, e.g., pixel intensities, spectral intensities, etc., reduces the dimension of the optimization problem compared to modelling of the electromagnetic response of ad hoc grating geometry. Thus, the magnitudes of dominant features of the modelled response are optimized during regression, rather than optimizing the values of structural parameters.

In some examples, the regression analysis performed by stacked structure measurement engine 150 includes both the parameters of interest characterizing the memory structure and the weighting coefficients of the logic signal model as regression parameters. However, in some other examples, only the parameters of interest characterizing the memory structure are treated as regression parameters, and the weighting coefficients of the logic signal model are treated as constant values.

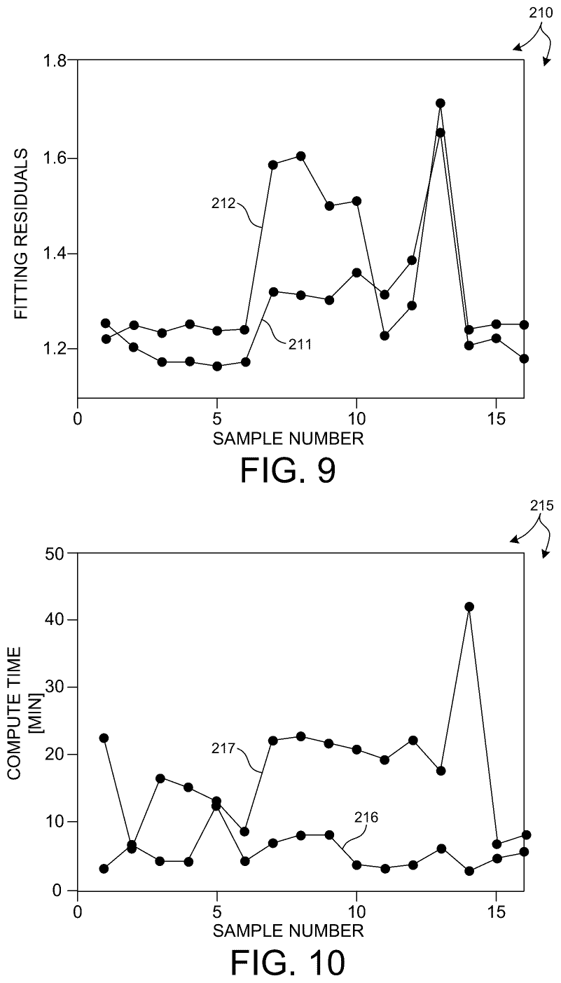

FIG. 9 depicts a plot 210 of fitting residuals associated with sixteen different measurements of stacked structures. Plotline 211 indicates the fitting residuals associated with measurements performed using stacked structure measurement engine 180. In this example, a principal component analysis was employed to characterize the scattering response of the logic structures at the detector and convolution was employed to combine the modelled signals associated with the logic and memory structures. Plotline 212 indicates the fitting residuals associated with measurements performed using an ad hoc grating model of the logic structures and a multi-model simulation approach. As depicted in FIG. 9, the fitting residuals associated with measurements performed using stacked structure measurement engine 180 are smaller across most measurement samples.

FIG. 10 depicts a plot 215 of computational time to result associated with the sixteen different measurements of stacked structures depicted in FIG. 9. Plotline 216 indicates the compute time associated with measurements performed using stacked structure measurement engine 180. Plotline 217 indicates the compute time associated with measurements performed using the ad hoc grating model of the logic structures and the multi-model simulation approach. As depicted in FIG. 10, the compute time associated with measurements performed using stacked structure measurement engine 180 are significantly smaller across almost all measurement samples.

In some embodiments, the scattering response of the logic structures in the absence of the memory structures is known at each measurement site under measurement. In some of these embodiments, parameters of interest characterizing the memory structures are estimated based on measurements of the stacked structure without a model of the scattering response of the logic structures.

In some examples, the set of signals indicative of the scattering response of the logic structure at each measurement site is measured before the memory structure is fabricated and before measurement of the stacked structure. In some examples, the set of signals indicative of the scattering response of the logic structure at each measurement site is derived from a library of samples measured before the memory structure is fabricated and before measurement of the stacked structure. In some of these examples, some or all of the measurement samples comprising the library are synthetically generated, i.e., generated by simulation.

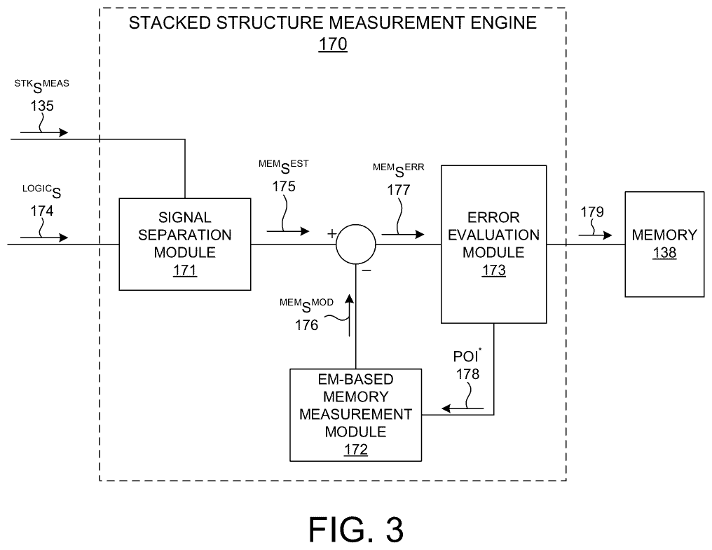

FIG. 3 is a diagram illustrative of a stacked structure measurement engine 170 implemented by computing system 130 in another embodiment. As depicted in FIG. 3, stacked structure measurement engine 170 includes signal separation module 171, electromagnetic based memory measurement module 172, and error evaluation module 173.

As depicted in FIG. 3, signals indicative of the known scattering response of the logic structure, ^{LOGIC}S 174, at the measurement sites and the measured scattering response of the stacked structure, ^{STK}S^{MEAS} 135, are received by signal separation module 171. Signal separation module 171 separates the known scattering response of the logic structures from the measured signals at each of the measurement sites to generate an estimated scattering response of the memory structures without the logic structure at the detector.

In some examples, the separation is determined as the difference between each corresponding element of the set of signals indicative of the scattering response of the logic structure without the memory structure and the detected signals indicative of the light scattered from the stacked structure. For example, at each pixel location, the difference between the detected signal indicative of the scattering response of the stacked structure and the signal indicative of the known scattering response of the logic structure is determined.

In some other examples, the separation is determined as a deconvolution of the set of signals indicative of the scattering response of the logic structure without the memory structure and the detected image of light scattered from the stacked structure.

As depicted in FIG. 3, stacked structure measurement engine 170 determines error signals, ^{MEM}S^{ERR} 177 based on a difference between the signals, ^{MEM}S^{EST} 175, indicative of the estimated scattering response of the memory structures without the logic structure at the detector and the set of signals, ^{MEM}S^{MOD} 176, indicative of the modelled scattering response of the memory structure. The electro-magnetic-based memory measurement module 172 employs an electromagnetic response simulator to predict the scattering response of the memory structure based on values of one or more parameters of interest characterizing the memory structure under measurement. The electromagnetic response simulator may be an analytical model or library-based simulator. In some embodiments, the electromagnetic response simulator is a trained, machine-learning based model of the electromagnetic response of the memory structure.

Error evaluation module 173 generates updated values of the parameters of interest, POI* 178, based on the error signals ^{MEM}S^{ERR} 177 as part of a regression analysis that minimizes the difference between the measured and modelled scattering response of the memory structure at the detector. The updated values of POI* 178 are communicated to EM-based memory measurement module 172 to update the modelled scattering response of the memory structure in a subsequent iteration of the regression. The regression analysis iterates until the error signals, ^{MEM}S^{ERR} 177, fall within acceptable limits, or the number of iterations reaches a limit. The resulting values of the parameters of interest 179 characterizing the memory structure are communicated to memory 138.

In another example, the known scattering response of the logic structures at the measurement sites is provided as the illumination input to the electromagnetic response model of the memory structures.

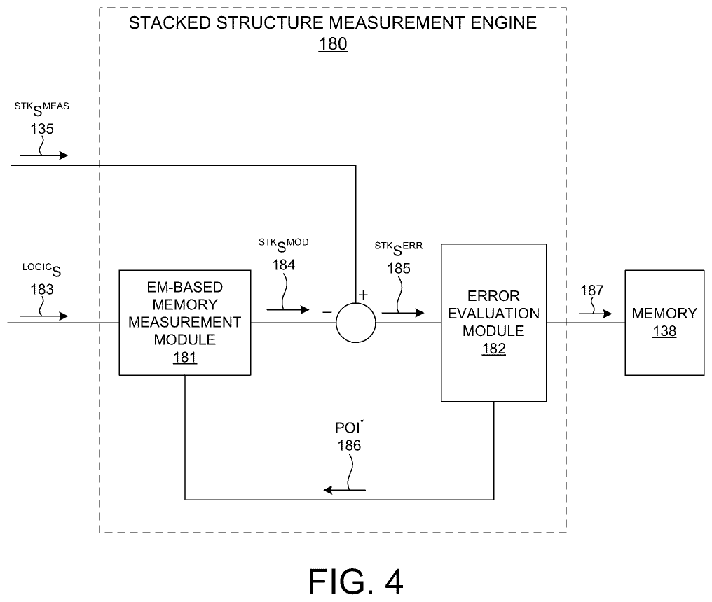

FIG. 4 is a diagram illustrative of a stacked structure measurement engine 180 implemented by computing system 130 in another embodiment. As depicted in FIG. 4, stacked structure measurement engine 180 includes electromagnetic based memory measurement module 181 and error evaluation module 182.

As depicted in FIG. 4, signals indicative of the known scattering response of the logic structure, ^{LOGIC}S 183, at the measurement sites are received by EM-based memory measurement module 181. The EM-based memory measurement module 181 employs an electromagnetic response simulator to predict the scattering response of the memory structure based on values of one or more parameters of interest characterizing the memory structure under measurement. The electromagnetic response simulator may be an analytical model or library-based simulator. In some embodiments, the electromagnetic response simulator is a trained, machine-learning based model of the electromagnetic response of the memory structure.

EM-based memory measurement module 181 employs the electromagnetic response model to generate an estimated scattering response of the stacked structure including the logic and memory structures by treating the known scattering response of the logic structure, ^{LOGIC}S 183, at each measurement site as an input to the EM simulation of the memory structure, i.e., the known scattering response of the logic structure is treated as the illumination beam incident on the memory structure. In this manner, the EM simulation of the memory structure approximates the scattering response of the stacked structure. EM-based memory measurement module 181 generates signals, ^{STK}S^{MOD} 184, indicative of the scattering response of the stacked structure. Signals, ^{STK}S^{MEAS} 135, indicative of the measured scattering response of the stacked structure are received by stacked structure measurement engine 180.

As depicted in FIG. 4, stacked structure measurement engine 180 determines error signals, ^{STK}S^{ERR} 185 based on a difference between the signals, ^{STK}S^{MOD} 184, indicative of the modelled scattering response of the stacked structure at the detector and the set of signals, ^{STK}S^{MEAS} 135, indicative of the measured scattering response of the stacked structure.

Error evaluation module 182 generates updated values of the parameters of interest, POI* 186, based on the error signals ^{STK}S^{ERR} 185 as part of a regression analysis that minimizes the difference between the measured and modelled scattering response of the stacked structure at the detector. The updated values of POI* 186 are communicated to EM-based memory measurement module 181 to update the modelled scattering response of the stacked structure in a subsequent iteration of the regression. The regression analysis iterates until the error signals, ^{STK}S^{ERR} 185, fall within acceptable limits, or the number of iterations reaches a limit. The resulting values of the parameters of interest 187 characterizing the memory structure are communicated to memory 138.

In some embodiments, the scattering response of the logic structures in the absence of the memory structures is unknown at any measurement site on a wafer, or set of wafers, under measurement. In some of these embodiments, a Fourier decomposition is employed to operate on signals, ^{STK}S^{MEAS} 135, indicative of the measured scattering response of the stacked structure. The Fourier decomposition separates the portion of the scattering response due to the logic structures and the scattering response due to the memory structures by spatial frequency. In these embodiments, logic structures are characterized by dominant pitch lengths that are significantly different from the dominant pitch lengths of the memory structures. Thus, a spatial Fourier decomposition of the measured response of the stacked structure separates the contributions to the measured signals by the logic structure and the memory structure by spatial frequency. In these embodiments, the spatial frequencies associated with the logic structures are selected and estimated signals indicative of the scattering response of the logic structure are generated by inverse Fourier transform. The resulting estimated signals can be employed for analysis by stacked structure measurement engines 150, 170, and 180, as described hereinbefore.

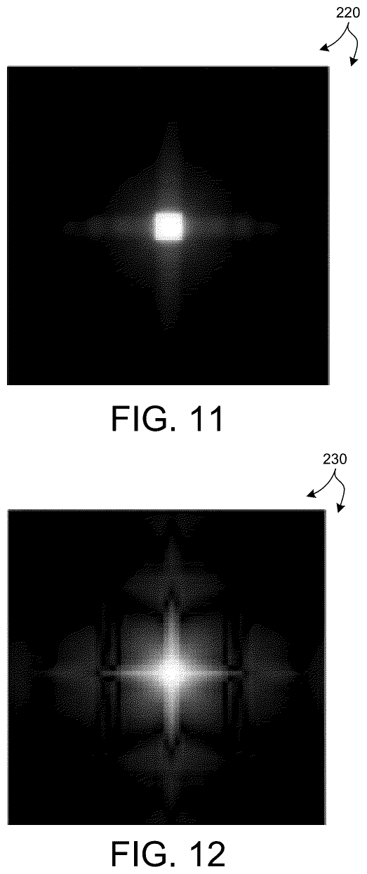

FIG. 11 is a plot 220 illustrative of the scattering response of logic structures at the detector plane.

FIG. 12 is a plot 230 illustrative of a Fourier decomposition of the scattering response of the logic structures at the detector plane.

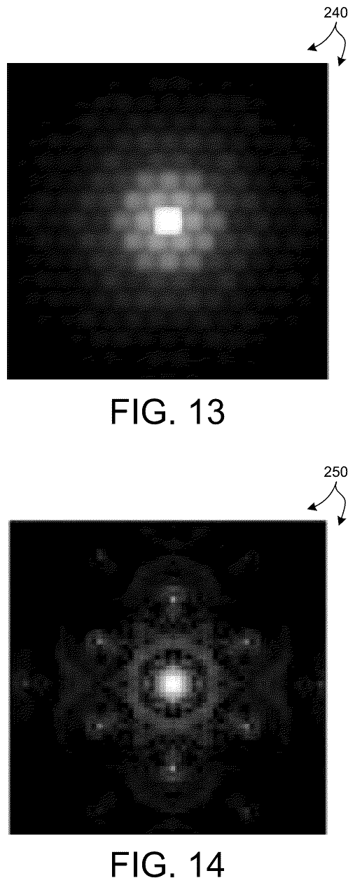

FIG. 13 is a plot 240 illustrative of the scattering response of memory structures at the detector plane.

FIG. 14 is a plot 250 illustrative of a Fourier decomposition of the scattering response of the memory structures at the detector plane.

As depicted in FIGS. 12 and 14, the spatial frequency characteristics of the scattering from the logic structures and the memory structures are substantially different, thus enabling separation in the frequency domain.

Measurements of stacked semiconductor structures as described herein may be employed as part of a semiconductor fabrication process in a number of different ways. In some embodiments, stacked structure measurement results are employed directly to control a fabrication process. In some examples, measured values of one or more parameters of interest, e.g., critical dimensions, are directly employed to control one or more process parameters, e.g., focus, dosage, etch time, etc.

In some embodiments, the structures under measurement include some amount of periodicity to scatter light in discernable discrete diffraction orders. Diffraction from structures exhibiting periodicity in two dimensions appears as discrete points on the image plane of the detector. Diffraction from structures exhibiting periodicity in one dimension appears as discrete points on a line in the image plane of the detector.

In some embodiments, the structures under measurement are quasi-periodic in one or both in-plane dimensions. In these embodiments, the diffraction images exhibit continuous lines of diffracted light.

In general, scatterometry based measurements as described herein may be employed to measure any semiconductor structure that exhibits periodicity or quasi-periodicity in one or both in-plane dimensions, e.g., the x-direction, the y-direction, or both.

Scatterometry based measurements, as described herein, may be performed using narrowband illumination light centered about any suitable illumination wavelength, e.g., narrowband illumination light centered about any wavelength suitable to transmit through the wafer and generate scattering from stacked structures. Although, in many measurement applications, the wavelength of illumination light is in the X-Ray range, in general, depending on the size of structures under measurement, the wavelength of illumination light may be in the optical range, including ultraviolet, visible, and infrared ranges. In preferred embodiments, the illumination light is narrow band with low beam divergence to reduce smearing of diffraction orders at the detector due to varying illumination wavelengths. Order separation on an X-Ray detector, specifically, is a function of wavelength, target periodicity, incidence angle, divergence angle of the uncollimated illumination light, detector resolution and distance from the target, etc. Nevertheless, in one dimension it is fundamentally governed by the diffraction equation, d*sin (Δθ)=λ, where d is the periodicity of the structure, λ is the illuminating wavelength and Δθ is the angular spacing between orders. From this equation or the two dimensional equivalent, a practitioner skilled in the art may quickly determine the bandwidth and beam divergence required to resolve the individual orders on a detector.

In general, scatterometry based measurements of stacked structures may be implemented by a wide variety of scatterometry based measurement systems employing narrow band illumination, including, but not limited to, X-Ray scatterometry based systems, including Small Angle X-Ray Scatterometry (SAXS) systems, etc.

Although useful measurements may be performed at two different incidence angles, in general, measurement sensitivity is improved by collecting measurement data over a large, diverse data set. This is achieved by collecting measurement data over a longer period of time, over a larger range of different illumination incidence angles, over a smaller spacing between different illumination incidence angles, or any combination thereof.

It should be recognized that the various steps described throughout the present disclosure may be carried out by a single computer system 130 or, alternatively, a multiple computer system 130. Moreover, different subsystems of the system 100, such as the specimen positioning system 140, may include a computer system suitable for carrying out at least a portion of the steps described herein. Therefore, the aforementioned description should not be interpreted as a limitation on the present invention but merely an illustration. Further, the one or more computing systems 130 may be configured to perform any other step (s) of any of the method embodiments described herein.

In addition, the computer system 130 may be communicatively coupled to the x-ray illumination source 110, beam shaping slit mechanism 120, specimen positioning system 140, and detector 119 in any manner known in the art. For example, the one or more computing systems 130 may be coupled to computing systems associated with the x-ray illumination source 110, beam shaping slit mechanism 120, specimen positioning system 140, and detector 119, respectively. In another example, any of the x-ray illumination source 110, beam shaping slit mechanism 120, specimen positioning system 140, and detector 119 may be controlled directly by a single computer system coupled to computer system 130.

The computer system 130 may be configured to receive and/or acquire data or information from the subsystems of the system (e.g., x-ray illumination source 110, beam shaping slit mechanism 120, specimen positioning system 140, detector 119, and the like) by a transmission medium that may include wireline and/or wireless portions. In this manner, the transmission medium may serve as a data link between the computer system 130 and other subsystems of the system 100.

Computer system 130 of the metrology system 100 may be configured to receive and/or acquire data or information (e.g., measurement results, modeling inputs, modeling results, etc.) from other systems by a transmission medium that may include wireline and/or wireless portions. In this manner, the transmission medium may serve as a data link between the computer system 130 and other systems (e.g., memory on-board metrology system 100, external memory, or external systems). For example, the computing system 130 may be configured to receive measurement data (e.g., signals 135) from a storage medium (i.e., memory 132 or 138) via a data link. For instance, image results obtained using detector 119 may be stored in a permanent or semi-permanent memory device (e.g., memory 132 or 138). In this regard, the measurement results may be imported from on-board memory or from an external memory system. Moreover, the computer system 130 may send data to other systems via a transmission medium. For instance, specimen parameter values 161, 179, and 187, determined by computer system 130 may be stored in a permanent or semi-permanent memory device (e.g., memory 138). In this regard, measurement results may be exported to another system.

Computing system 130 may include, but is not limited to, a personal computer system, mainframe computer system, cloud-based computing system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

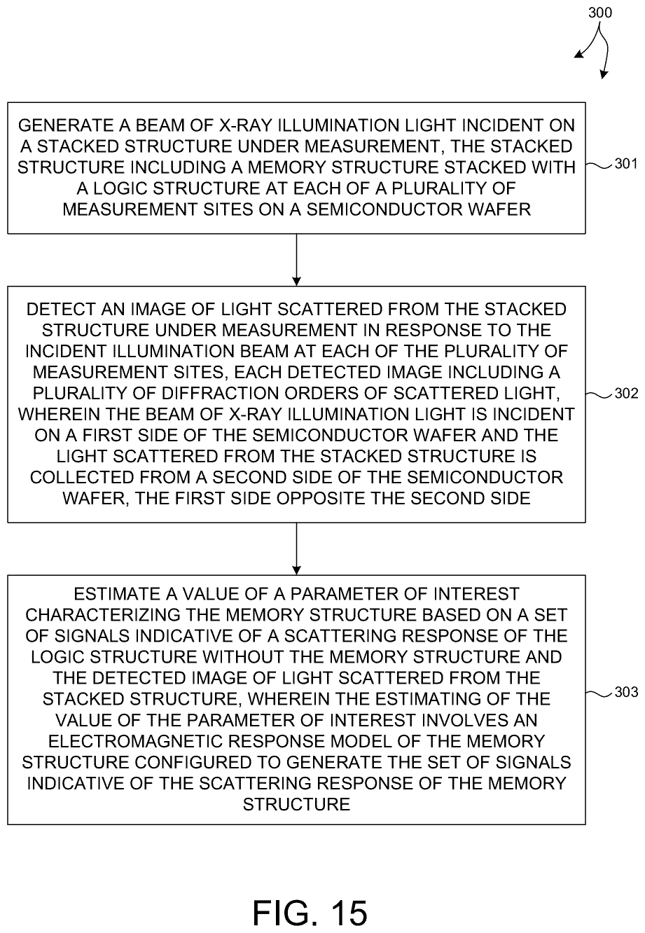

FIG. 15 illustrates a method 300 suitable for implementation by the metrology system 100 of the present invention. In one aspect, it is recognized that data processing blocks of method 300 may be carried out via a pre-programmed algorithm executed by one or more processors of computing system 130. While the following description is presented in the context of metrology system 100, it is recognized herein that the particular structural aspects of metrology system 100 do not represent limitations and should be interpreted as illustrative only.

In block 301, a beam of x-ray illumination light incident on a stacked structure under measurement is generated. The stacked structure includes a memory structure stacked with a logic structure at each of a plurality of measurement sites on a semiconductor wafer.

In block 302, an image of light scattered from the stacked structure under measurement is detected in response to the incident illumination beam at each of the plurality of measurement sites. Each detected image includes a plurality of diffraction orders of scattered light. The beam of x-ray illumination light is incident on a first side of the semiconductor wafer and the light scattered from the stacked structure is collected from a second side of the semiconductor wafer. The first side is opposite the second side.

In block 303, a value of a parameter of interest characterizing the memory structure is estimated based on a set of signals indicative of a scattering response of the logic structure without the memory structure and the detected image of light scattered from the stacked structure. The estimating of the value of the parameter of interest involves an electromagnetic response model of the memory structure configured to generate the set of signals indicative of the scattering response of the memory structure.

In some embodiments, scatterometry measurements as described herein are implemented as part of a fabrication process tool. Examples of fabrication process tools include, but are not limited to, lithographic exposure tools, film deposition tools, implant tools, and etch tools. In this manner, the results of a T-SAXS analysis are used to control a fabrication process. In one example, T-SAXS measurement data collected from one or more targets is sent to a fabrication process tool. The T-SAXS measurement data is analyzed as described herein and the results used to adjust the operation of the fabrication process tool.

Scatterometry measurements as described herein may be used to determine characteristics of a variety of semiconductor structures. Exemplary structures include, but are not limited to, FinFETs, low-dimensional structures such as nanowires or graphene, sub 10 nm structures, lithographic structures, through substrate vias (TSVs), memory structures such as DRAM, DRAM 4F2, FLASH, MRAM and high aspect ratio memory structures. Exemplary structural characteristics include, but are not limited to, geometric parameters such as line edge roughness, line width roughness, pore size, pore density, side wall angle, profile, critical dimension, pitch, thickness, overlay, and material parameters such as electron density, composition, grain structure, morphology, stress, strain, and elemental identification. In some embodiments, the metrology target is a periodic structure. In some other embodiments, the metrology target is aperiodic.

In some examples, measurements of critical dimensions, thicknesses, overlay, and material properties of stacked ratio semiconductor structures including, but not limited to, spin transfer torque random access memory (STT-RAM), three dimensional NAND memory (3D-NAND) or vertical NAND memory (V-NAND), dynamic random access memory (DRAM), three dimensional FLASH memory (3D-FLASH), resistive random access memory (Re-RAM), and phase change random access memory (PC-RAM) are performed with T-SAXS measurement systems as described herein.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including critical dimension applications and overlay metrology applications. However, such terms of art do not limit the scope of the term “metrology system” as described herein. In addition, the metrology systems described herein may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the measurement techniques described herein.

Various embodiments are described herein for a semiconductor processing system (e.g., an inspection system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, XRF disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
an x-ray illumination source configured to generate a beam of x-ray illumination light incident on a stacked structure under measurement, the stacked structure including a memory structure stacked with a logic structure at each of a plurality of measurement sites on a semiconductor wafer;
an imaging detector configured to detect an image of light scattered from the stacked structure under measurement in response to the incident illumination beam at each of the plurality of measurement sites, each detected image including a plurality of diffraction orders of scattered light, wherein the beam of x-ray illumination light is incident on a first side of the semiconductor wafer and the light scattered from the stacked structure is collected from a second side of the semiconductor wafer, the first side opposite the second side; and
a computing system configured to:
estimate a value of a parameter of interest characterizing the memory structure based on a set of signals indicative of a scattering response of the logic structure without the memory structure and the detected image of light scattered from the stacked structure, wherein the estimating of the value of the parameter of interest involves an electromagnetic response model of the memory structure configured to generate the set of signals indicative of the scattering response of the memory structure.

2. The metrology system of claim 1, wherein the beam of x-ray illumination light is incident on the logic structure and scatters from the logic structure onto the memory structure or the beam of x-ray illumination light is incident on the memory structure and scatters from the memory structure onto the logic structure.

3. The metrology system of claim 1, the computing system further configured to:
combine the set of signals indicative of the scattering response of the logic structure and the set of signals indicative of the scattering response of the memory structure; and
determine a difference between the combined set of signals and the detected image of light scattered from the stacked structure, wherein the estimating of the value of the parameter of interest involves a regression analysis that minimizes the difference between the combined set of signals and the detected image of light scattered from the stacked structure.

4. The metrology system of claim 3, wherein the combining of the set of signals indicative of the scattering response of the logic structure and the set of signals indicative of the scattering response of the memory structure involves a summation of each corresponding element of the set of signals indicative of the scattering response of the logic structure and the set of signals indicative of the scattering response of the memory structure.

5. The metrology system of claim 3, wherein the combining of the set of signals indicative of the scattering response of the logic structure and the set of signals indicative of the scattering response of the memory structure involves a convolution of the set of signals indicative of the scattering response of the logic structure with the set of signals indicative of the scattering response of the memory structure or a convolution of the set of signals indicative of the scattering response of the memory structure with the set of signals indicative of the scattering response of the logic structure.

6. The metrology system of claim 3, the computing system further configured to:
generate the set of signals indicative of the scattering response of the logic structure without the memory structure based on a logic signal model, wherein the logic signal model is a model of pixel intensities at the detector characterized by one or more basis functions and corresponding coefficient values.

7. The metrology system of claim 6, the computing system further configured to:
determine the one or more basis functions and initial values of the corresponding coefficients based on an analysis of a library of measured values indicative of the scattering response of the logic structures without the memory structure, a library of simulated values indicative of the scattering response of the logic structures without the memory structure, or both.

8. The metrology system of claim 7, wherein the analysis involves a principal component analysis or a discrete cosine transform analysis.

9. The metrology system of claim 8, the computing system further configured to:
estimate a value of each of the corresponding coefficients, wherein the estimating of the value of each of the corresponding coefficients involves the regression analysis that minimizes the difference between the combined set of signals and the detected image of light scattered from the stacked structure.

10. The metrology system of claim 1, wherein the set of signals indicative of the scattering response of the logic structure without the memory structure at the one or more measurement sites is measured before the image of light scattered from the stacked structure is measured.

11. The metrology system of claim 10, the computing system further configured to:
separate the set of signals indicative of the scattering response of the logic structure without the memory structure from the detected image of light scattered from the stacked structure to generate a separated set of signals indicative of the scattering response of the memory structure without the logic structure;
determine a difference between the separated set of signals indicative of the scattering response of the memory structure without the logic structure and the set of signals indicative of the scattering response of the memory structure, wherein the estimating of the value of the parameter of interest involves a regression analysis that minimizes the difference between the separated set of signals indicative of the scattering response of the memory structure without the logic structure and the set of signals indicative of the scattering response of the memory structure.

12. The metrology system of claim 11, wherein the separating of the set of signals indicative of the scattering response of the logic structure without the memory structure from the detected image of light scattered from the stacked structure involves a difference between each corresponding element of the set of signals indicative of the scattering response of the logic structure without the memory structure and the detected image of light scattered from the stacked structure.

13. The metrology system of claim 11, wherein the separating of the set of signals indicative of the scattering response of the logic structure without the memory structure from the detected image of light scattered from the stacked structure involves a deconvolution of the set of signals indicative of the scattering response of the logic structure without the memory structure and the detected image of light scattered from the stacked structure.

14. The metrology system of claim 1, the computing system further configured to:
generate the set of signals indicative of the scattering response of the logic structure without the memory structure based on a Fourier decomposition of the detected image of light scattered from the stacked structure.

15. A method comprising:
generating a beam of x-ray illumination light incident on a stacked structure under measurement, the stacked structure including a memory structure stacked with a logic structure at each of a plurality of measurement sites on a semiconductor wafer;
detecting an image of light scattered from the stacked structure under measurement in response to the incident illumination beam at each of the plurality of measurement sites, each detected image including a plurality of diffraction orders of scattered light, wherein the beam of x-ray illumination light is incident on a first side of the semiconductor wafer and the light scattered from the stacked structure is collected from a second side of the semiconductor wafer, the first side opposite the second side; and
estimating a value of a parameter of interest characterizing the memory structure based on a set of signals indicative of a scattering response of the logic structure without the memory structure and the detected image of light scattered from the stacked structure, wherein the estimating of the value of the parameter of interest involves an electromagnetic response model of the memory structure configured to generate the set of signals indicative of the scattering response of the memory structure.

16. The method of claim 15, further comprising:
combining the set of signals indicative of the scattering response of the logic structure and the set of signals indicative of the scattering response of the memory structure; and
determining a difference between the combined set of signals and the detected image of light scattered from the stacked structure, wherein the estimating of the value of the parameter of interest involves a regression analysis that minimizes the difference between the combined set of signals and the detected image of light scattered from the stacked structure.

17. The method of claim 16, wherein the combining of the set of signals indicative of the scattering response of the logic structure and the set of signals indicative of the scattering response of the memory structure involves a summation of each corresponding element of the set of signals indicative of the scattering response of the logic structure and the set of signals indicative of the scattering response of the memory structure.

18. The method of claim 16, wherein the combining of the set of signals indicative of the scattering response of the logic structure and the set of signals indicative of the scattering response of the memory structure involves a convolution of the set of signals indicative of the scattering response of the logic structure with the set of signals indicative of the scattering response of the memory structure or a convolution of the set of signals indicative of the scattering response of the memory structure with the set of signals indicative of the scattering response of the logic structure.

19. The method of claim 16, further comprising:
generating the set of signals indicative of the scattering response of the logic structure without the memory structure based on a logic signal model, wherein the logic signal model is a model of pixel intensities at the detector characterized by one or more basis functions and corresponding coefficient values.

20. A metrology system comprising:
an x-ray illumination source configured to generate a beam of x-ray illumination light incident on a stacked structure under measurement, the stacked structure including a memory structure stacked with a logic structure at each of a plurality of measurement sites on a semiconductor wafer;
an imaging detector configured to detect an image of light scattered from the stacked structure under measurement in response to the incident illumination beam at each of the plurality of measurement sites, each detected image including a plurality of diffraction orders of scattered light, wherein the beam of x-ray illumination light is incident on a first side of the semiconductor wafer and the light scattered from the stacked structure is collected from a second side of the semiconductor wafer, the first side opposite the second side; and
a non-transitory, computer-readable medium storing instructions that, when executed by one or more processors, causes the one or more processors to:
estimate a value of a parameter of interest characterizing the memory structure based on a set of signals indicative of a scattering response of the logic structure without the memory structure and the detected image of light scattered from the stacked structure, wherein the estimating of the value of the parameter of interest involves an electromagnetic response model of the memory structure configured to generate the set of signals indicative of the scattering response of the memory structure.
